(19) United States
(12) Patent Application Publication
(10) Pub. No.: US 2005/0012114 A1
(43) Pub. Date: Jan. 20, 2005

(54) Metal-oxide-semiconductor field-effect transistor

(75) Inventors: Hiromi Tada, Hyogo-ken (JP); Yoshiaki Aizawa, Kanagawa-ken (JP); Toshimitsu Kato, Fukuoka-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/860,509

(22) Filed: Jun. 4, 2004

(30) Foreign Application Priority Data
Jun. 4, 2003 (JP) P2003-159574

(51) Int. Cl. H01L 31/0328

(52) U.S. Cl. 257/192

(57) ABSTRACT

An up-drain type MOSFET device is formed in a limited n⁺ diffusion region used for an up-drain structure with the reduction of increase in a chip area which would otherwise be required for such device. Trench 112 is made separately from device regions provided in n⁻-type exitaxial layer 101. Trench 112 reaches to n⁺ implanted layer 111 while deeply diffused n⁺ region 110 is formed along a sidewall of trench 112 by applying slant implantation thereby to form an up-drain structure.

### FIELD OF THE INVENTION

This invention relates to a metal-oxide-semiconductor field-effect transistor (“MOSFET”) device and, more particularly, to an up-drain type power MOSFET device.

This application is based upon and claims the benefit of priority from the prior Japanese Patent Application No. 2003-159574, filed on Jun. 4, 2003, the entire contents of which is incorporated in this application by reference.

### BACKGROUND OF THE INVENTION

A power MOSFET device used for an automobile, for instance, generally requires low turned-on resistance, high-serge durability, and low production cost. In discrete power MOSFET devices, there have been a vertical double-diffusion type MOSFET device and an up-drain type power MOSFET device. The drain electrode of the former is ordinarily arranged on the bottom of its substrate. The latter, i.e., the up-drain type power MOSFET device, is a composite integrated circuit in which a power MOSFET device, bi-polar transistors, and complementary MOSFET devices are integrated on a single chip. The up-drain type power MOSFET device, however, is provided with the drain electrode formed on the surface of its substrate although the drain electrode is formed on the bottom of a substrate in the case of the vertical double-diffusion MOSFET device.

A conventional up-drain type power MOSFET device is shown in FIG. 6 (see Japanese Unexamined Patent Publication 2001-127294). The MOSFET device includes silicon substrate 100, n⁻-type epitaxial layer 101 formed on silicon substrate 100 and p-type well regions 102 in upper portions close to the upper surface of n⁻-type epitaxial layer 101. Each p-type well region 102 is provided with n⁺ region 103 and p⁺ region 104. P-type well region 102 is connected to the source electrode S. Neighboring p-type well regions 102 are connected to gate electrodes G through gate insulation films 106 formed on the upper surface of p-type well regions 102. N⁺ region 108 is formed in the upper portions close to the upper surface of n⁻-type epitaxial layer 101 but is apart from p-type well regions 102. Further, n⁺ region 108 is connected to the drain electrode D.

Since the drain electrode D of such an up-drain type power MOSFET device is connected to n⁺ region 108 formed in the upper portions close to the upper surface of n⁻-type epitaxial layer 101, its turned-on resistance increases significantly in comparison with that of a vertical double-diffusion MOSFET device, the drain electrode of which is connected to a portion close to the lower surface of the silicon substrate.

In order to decrease the turned-on resistance, a drain region is provided with deeply diffused n⁺ region 110 connected to the drain electrode D and n⁺ implanted layer 111 to which deeply diffused n⁺ region 110 reaches as shown in FIGS. 7 and 8 (see also Japanese Unexamined Patent Publication No. 2001-127294). Since the other components are basically the same as those shown in FIG. 6, the same reference numerals and symbols are used for them and their explanations are not repeated here.

When n⁺ implanted layer 111 of the up-drain type power MOSFET device is formed deeply in n⁻-type epitaxial layer 101, a diffused length of deeply diffused n⁺ region 110 is necessarily several tens of microns (μm) or longer if the power MOSFET device is designed for high-voltage use. Thus, it takes fairly long diffusion time and a large region is necessary for deeply diffused n⁺ region 110 of the up-drain structure in consideration of possible side diffusion so that a chip area of the up-drain type power MOSFET device increases. In addition, when epitaxial and diffusion processes are repeated to form more deeply diffused n⁺ region 110 as shown in FIG. 8, a complicated production process and expensive production cost are required.

### SUMMARY OF THE INVENTION

Accordingly, the present invention provides an up-drain type power MOSFET device formed in a limited region used for a deeply diffused n⁺ region with the reduction of increase in its chip area which would otherwise be required for such device.

The first aspect of the present invention is directed to a metal-oxide-semiconductor field effect transistor device provided with a substrate, a first electrically conductive type semiconductor layer formed on the substrate, a first electrically conductive type implanted semiconductor layer, impurity concentration of which is more than that of the first electrically conductive type semiconductor layer, a second electrically conductive type semiconductor channel region formed in a portion close to a upper surface of the first electrically conductive type semiconductor layer, a first electrically conductive type source region formed in a portion close to a surface of the second electrically conductive type semiconductor channel region, a gate insulation film formed on at least a part of the second electrically conductive type semiconductor channel region, a gate electrode disposed on the gate insulation film, a trench defined by sidewalls made in the first electrically conductive type semiconductor layer, and a deep drain region formed along one of the sidewalls reaching from the portion close to the upper surface of the first electrically conductive type semiconductor layer to the first electrically conductive type implanted semiconductor layer.

The second aspect of the present invention is directed to a metal-oxide-semiconductor field-effect transistor device in which inner walls of the trench are coated with SiO₂ films or Si₃N₄ films and the trench is filled with polysilicon.

The third aspect of the present invention is directed to a metal-oxide-semiconductor field-effect transistor device in which the substrate or the first electrically conductive type semiconductor layer is a dielectric insulation wafer substrate.

### BRIEF DESCRIPTION OF THE DRAWINGS

A more complete appreciation of the present invention and many of its attendant advantages will be readily obtained as the same becomes better understood by reference to the following detailed descriptions when considered in connection with the accompanying drawings, wherein:

FIG. 1 is a cross-sectional view of an up-drain type power MOSFET device of the first embodiment of the present invention;

FIG. 2 is a cross-sectional view of a deep trench type power MOSFET device of the second embodiment of the present invention;

FIG. 3 is a cross-sectional view of a power MOSFET device formed on a dielectric insulation wafer of the third embodiment of the present invention;

FIGS. 4 and 5 are cross-sectional views of power MOSFET devices formed on dielectric insulation wafers of the other embodiments of the present invention, respectively; and

FIGS. 6 through 8 are cross-sectional views of conventional up-drain type MOSFET devices.

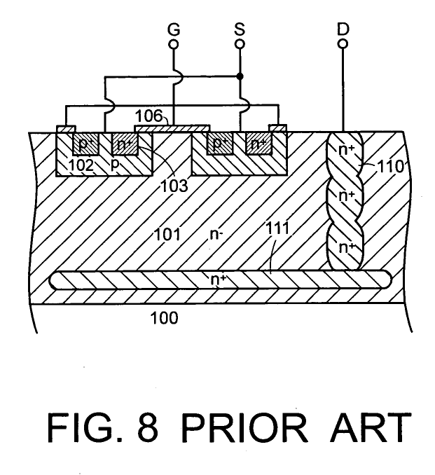

### DESCRIPTION OF THE EMBODIMENTS

Embodiments of the present invention will be explained below with reference to the attached drawings. It should be noted that the present invention is not limited to the embodiments but covers their equivalents. Throughout the attached drawings, similar or same reference numerals show similar, equivalent or same components.

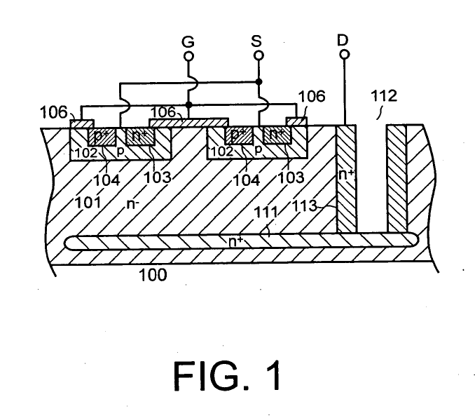

FIG. 1 is a cross-sectional view of an up-drain type power MOSFET device of the first embodiment of the present invention. The MOSFET device includes silicon substrate 100, n⁻-type epitaxial layer 101 formed on silicon substrate 100 and p-type well regions 102 in upper portions close to the upper surface of n⁻-type epitaxial layer 101. Each p-type well region 102 is provided with n⁺ region 103 and p⁺ region 104. P-type well region 102 is connected to the source electrode S. Neighboring p-type well regions 102 are connected to gate electrodes G through gate insulation films 106 formed on the upper surface of p-type well regions 102. N⁺ implanted layer 111 is formed in a deep region of n⁻-type epitaxial layer 101. Vertical n⁺ region 113 is provided in n⁻-type epitaxial layer 101 but horizontally apart from p-type well regions 102. Vertical n⁺ region 113 is connected to the drain electrode D.

Trench 112 is formed in a region horizontally separated from p-type well regions 102. As shown in FIG. 1, trench 112 reaches to n⁺ implanted layer 111. Vertical n⁺ region 113 is formed along trench 112 by applying a slant implantation of phosphorous to trench 112, for instance. Vertical n⁺ region 113 is connected to the drain electrode D and n⁺ implanted layer 111 to form an up-drain structure. Conditions on the implantation and thermal diffusion are set as follows: a phosphorous concentration of 7×10¹⁵ cm⁻², acceleration energy of 100 KeV, a temperature of 1,170° C. and process time of 10 hrs. The thermal treatment is carried out for such long time at such high temperature for vertical n⁺ region 113 to sufficiently overlap n⁺ implanted layer 111. After inner walls of trench 112 are coated with SiO2 films or Si3N4 films, the trench is filled with polysilicon.

According to the first embodiment of the present invention, even though n⁺ implanted layer 111 is several tens of microns in depth, vertical n⁺ region 113 can be formed through a trench width of 10 μm. Thus, it is possible to form trench 112 and n⁺ region 113 with a total width of 10 μm+α so that an increase in a chip area of the up-drain type power MOSFET device which would otherwise be required for such device can be remarkably reduced.

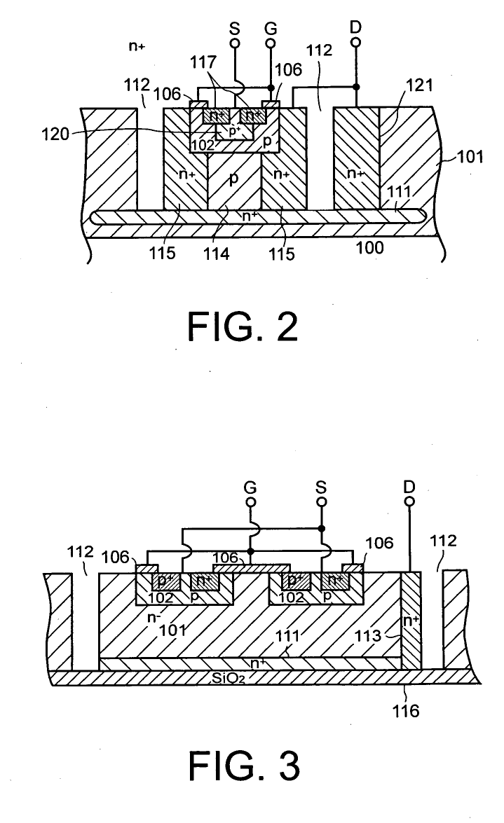

Next, the other embodiments will be described with reference to FIGS. 2 through 5. Since the same reference numerals and symbols as shown in FIG. 1 represent the same components in the drawings, only different components will be described below.

FIG. 2 is a cross-sectional view of a deep trench type power MOSFET device of the second embodiment of the present invention. P⁺ drift layer 120 is formed in p-type well region 102 and n⁺ drift layers 117 are formed at both upper portions on p⁺ drift layer 120, also in p-type well region 102. Trench 112 extends from the upper surface of n⁻-type epitaxial layer 101 to n⁺ implanted layer 111. Trench 112 is formed by applying a dry etching process, for example. After inner walls of trench 112 are coated with SiO2 films or Si3N4 films, polysilicon is filled into trench 112. The gate electrode G is formed over channel regions that are between two n⁺ drift regions 117 and n⁺ drift regions 115, and through gate insulation films 106. The source electrode is connected to p⁺ drift layer 120 in p-type well region 102. P-layer is formed between n⁺ drift regions 117 and under p-type well region 102. N⁺ drift regions 115 are formed by applying implantation through sidewalls of trenches 112, which is similar to the implantation to vertical n⁺ region 113 shown in FIG. 1.

Since deep trenches 112 and n⁺ drift regions 115 of the deep trench type power MOSFET device in this embodiment can be made at the same time and no additional process is required to make trenches 112 for the up-drain electrodes D, the increase in production cost which would otherwise be required for such device can be substantially reduced.

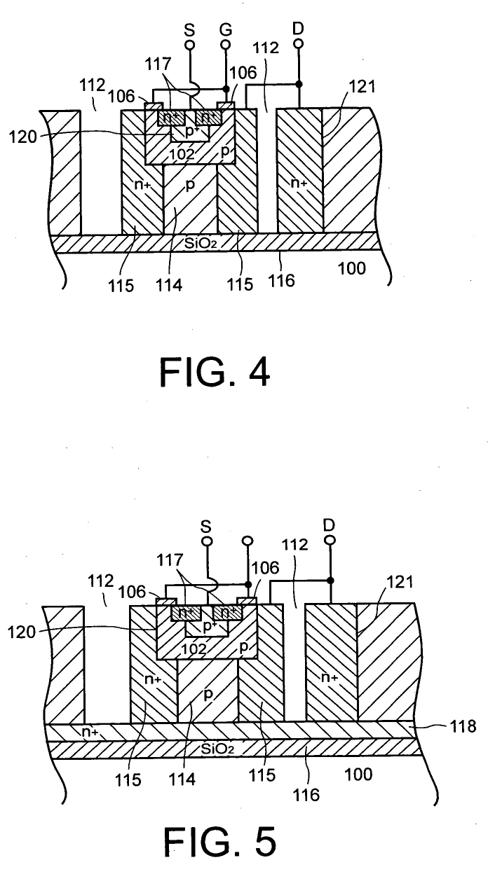

FIG. 3 is a cross-sectional view of a power MOSFET device formed on a dielectric insulation wafer substrate in accordance with the third embodiment of the present invention, which is a major application of the up-drain type power MOSFET device. The dielectric insulation wafer substrate is a kind of silicon-on-insulator (SOI) wafer made of a high insulation oxidation layer formed in the inside of the wafer to isolate semiconductor devices from each other in island-like shapes. In this embodiment, insulation layer 116, such as an SiO₂ substrate, is used in place of silicon substrate 100 of FIG. 1. N⁺ implanted layer 111, n⁻-type epitaxial layer 101 and a MOSFET device are formed on insulation layer 116 in that order. Trenches 112 used for the isolation of devices are made so as to reach from the upper surface of n⁻-type epitaxial layer 101 to the upper surface of insulation layer 116 by applying a dry etching process, for instance. Vertical n⁺ region 113 is formed along the wall of trench 112 on the device side and connected to the drain electrode D. After inner walls of trench 112 are coated with SiO2 films or Si3N4 films, polysilicon is filled into the trench 112. Since this embodiment also requires no additional process to make trenches 112 for vertical n⁺ region 113, the increase in production cost which would otherwise be required for such device can be reduced.

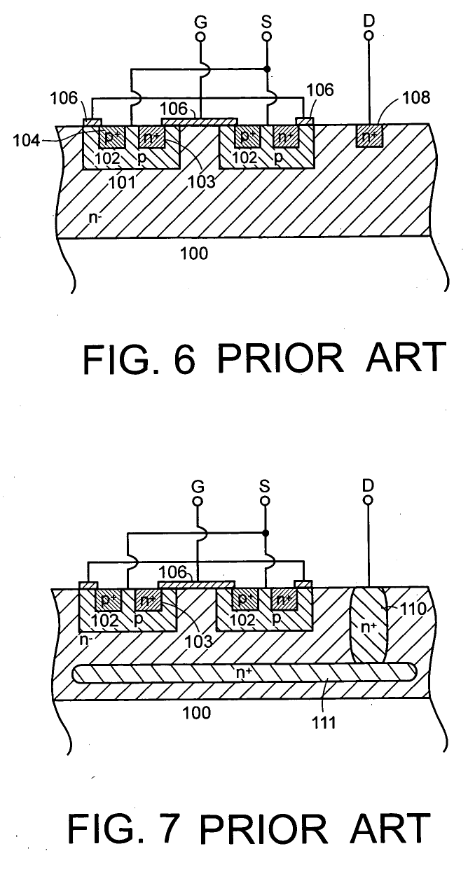

FIGS. 4 and 5 are cross-sectional views of deep trench type power MOSFET devices formed on dielectric insulation wafer substrates of the other embodiments of the present invention. The deep trench type power MOSFET devices are basically the same as the MOSFET device shown in FIG. 2 except for the structure of substrates. In these embodiments, insulation layers 116 made of SiO₂ are formed on silicon substrate 100, respectively. Further, n⁺ layer 118 is formed on insulation layer 116 in the embodiment shown in FIG. 5.

The present invention is not limited to the embodiments described above. Although the invention has been described in its applied form with a certain degree of particularity, it is understood that the present disclosure of the preferred form can be changed in the details of construction and the combination and arrangement of components may be resorted to without departing from the spirit and the scope of the invention as hereinafter claimed. Some components of the embodiments may be eliminated or various components from different embodiments may also be combined.

An up-drain type MOSFET device of the present invention does not require a large n⁺ diffusion region used for an up-drain structure or the increase in its chip area which would otherwise be required for such device.

1. A metal-oxide-semiconductor field-effect transistor device, comprising:
a substrate;
a first electrically conductive type semiconductor layer formed on said substrate;
a first electrically conductive type implanted semiconductor layer, impurity concentration of which is more than that of said first electrically conductive type semiconductor layer;
a second electrically conductive type semiconductor channel region formed in a portion close to an upper surface of said first electrically conductive type semiconductor layer;
a first electrically conductive type source region formed in a portion close to an upper surface of said second electrically conductive type semiconductor channel region;
a gate insulation film formed on at least a part of said second electrically conductive type semiconductor channel region;
a gate electrode disposed on said gate insulation film;
a trench defined by sidewalls made in said first electrically conductive type semiconductor layer; and
a deep drain region formed along one of said sidewalls reaching from the portion close to the upper surface of said first electrically conductive type semiconductor layer to said first electrically conductive type implanted semiconductor layer.

2. A metal-oxide-semiconductor field-effect transistor device according to claim 1, wherein inner walls of said trench are coated with SiO₂ films or Si₃N₄ films and said trench is filled with polysilicon.

3. A metal-oxide-semiconductor field-effect transistor device according to claim 1, wherein said substrate or said first electrically conductive type semiconductor layer is a dielectric insulation wafer substrate.

4. A metal-oxide-semiconductor field effect transistor device, comprising:
a substrate;
a first layer formed on said substrate, said first layer including a channel region, a source region and a gate region in an upper portion of the first layer;
a trench formed from an upper surface of said first layer to said second layer, said trench having a sidewall; and
a drain region with a deeply-doped impurity formed in said sidewall.

5. A metal-oxide-semiconductor field effect transistor device according claim 4, wherein the first layer has a first electrically conductive type semiconductor with a first impurity concentration, and
the second layer has a first electrically conductivity type semiconductor with a second impurity concentration which is higher than the first impurity concentration.

6. A metal-oxide-semiconductor field effect transistor device according claim 4, wherein the first layer has a first electrically conductivity type semiconductor, and
the second layer has a second electrically conductivity type semiconductor which is different from the first electrically conductivity type semiconductor.

7. A metal-oxide-semiconductor field effect transistor device, comprising:
a dielectric insulation substrate;
a first layer formed on the dielectric insulation substrate;
a channel region formed in an upper portion of the first layer;
a source region formed in an upper portion of the first layer;
a gate region formed in an upper portion of the first layer;
a trench formed from an upper surface of the first layer to the dielectric insulation substrate, the trench having a sidewall; and
a drain region with deeply-doped-impurity formed in the sidewall.
